(19) United States
(12) Patent Application Publication
(10) Pub. No.: US 2016/0268238 A1
(43) Pub. Date: Sep. 15, 2016

(54) LED PACKAGE

(71) Applicant: LITECOOL LIMITED, Sheffield (GB)

(72) Inventors: James Reeves, Nottingham (GB); Andrew Young, Sheffield (GB)

(21) Appl. No.: 15/031,840

(22) PCT Filed: Oct. 23, 2014
(86) PCT No.: PCT/GB2014/053153

§ 371 Date: Apr. 25, 2016

(30) Foreign Application Priority Data
Oct. 25, 2013 (GB) 1318911.3

(51) Int. Cl. H01L 25/075; H01L 33/62; H01L 25/00; H01L 33/48

(52) U.S. Cl. CPC H01L 25/0756; H01L 33/486; H01L 33/62; H01L 25/50; H01L 2933/0066

(57) ABSTRACT

According to a first aspect there is provided a light emitting diode (LED) package. The LED package comprises a conductive layer disposed on a non-conductive substrate, a plurality of high aspect ratio cavities extending through the conductive layer thereby separating the conductive layer into a plurality of electrical tracks,and one or more LED die mounted on to an exposed surface of the conductive layer, each of the one or more LED die having a first electrode in electrical contact with one of the electrical tracks.

The present invention relates to light emitting diodes and relates particularly but not exclusively to an improved LED package, and a method of manufacturing an improved LED package.

A light-emitting diode (LED) is a p-n junction semiconductor diode that emits photons when a current is applied, where the amount of light emitted is proportional to the current.

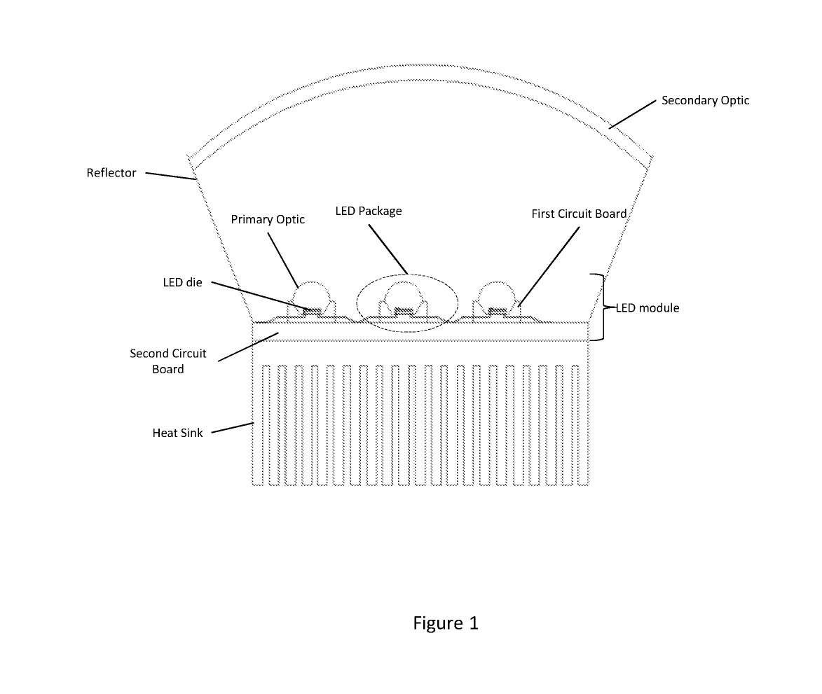

Before an LED die can be used in a practical application it must be packaged and assembled into an LED device, referred to as luminaire or lamp. For example, FIG. 1 illustrates a conventional LED luminaire that is comprised of a number LED die that are each mounted onto a first circuit board to form an LED package, and each LED package is then mounted onto a further circuit board to form an LED module, with the LED module then being mounted onto a heat-sink which is exposed to ambient air.

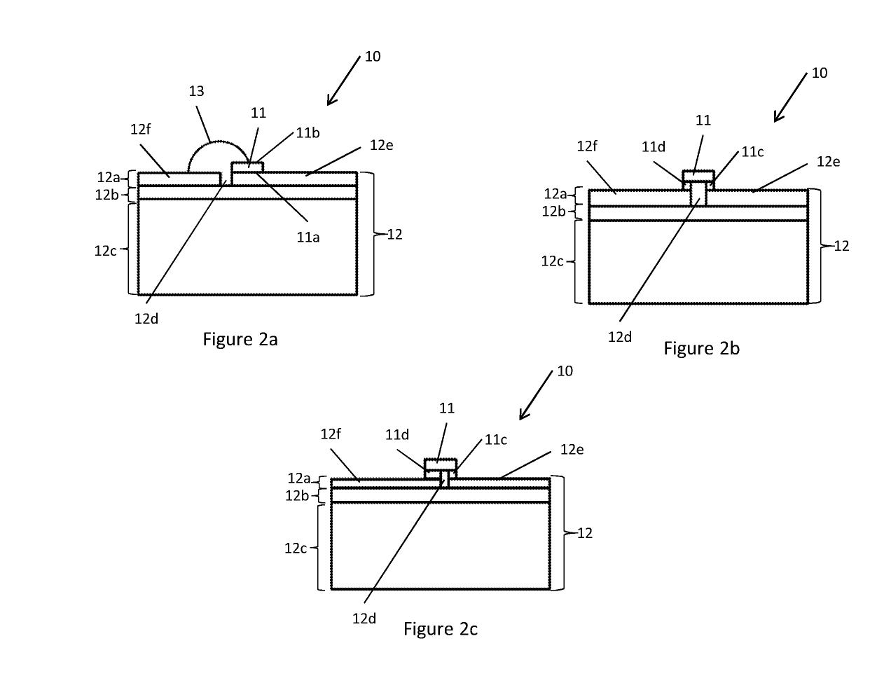

FIGS. 2a, 2b, and 2c illustrate schematically three examples of a conventional LED package 10 in which a single LED die 11 is mounted onto circuit board 12, wherein the circuit board 12 consists of three layers; a top copper layer 12a, a non-conductive substrate layer 12b, and a bottom metal layer 12c. The top copper layer 12a of the circuit board 12 is etched to form one or more cavities 12d, wherein the cavities separate portions of the top copper layer 12a so as to define a number of electrical tracks 12e, 12f.

FIG. 2a illustrates schematically an example of a conventional LED package 10 that includes an LED die 11 that has a vertical structure/architecture. In this regard, vertical LED die are formed such that the electrical contacts/electrodes are provided on opposite sides of the LED die (i.e. on the top and bottom). The LED die 11 illustrated in FIG. 2a therefore has a first electrode (not shown) provided on a first (lower) surface 11a of the LED die 11 that is bonded to a first electrical track 12e of the circuit board 12, and a second electrode (not shown) provided on a second (upper) surface 11b of the LED die 11 that is connected to a second electrical track 12f of the circuit board 12 by a wire bond 13.

FIG. 2b illustrates schematically an example of a conventional LED package 10 that includes an LED die 11 that has a lateral/horizontal structure/architecture. In this regard, lateral LED die are formed such that both of the electrical contacts/electrodes are provided on the same side of the die (i.e. on the top or bottom). Face-up lateral LED die have both the p-electrode and n-electrode on the top side of the LED die (i.e. the side from which light exits the LED die), whilst flip-chip lateral LED die have both the p-electrode and n-electrode on the bottom side of the LED die (i.e. the side opposite to that from which light exits the LED die).

The LED die 11 illustrated in FIG. 2b is a flip-chip LED die and therefore has a first electrode 11c provided on the first (lower) surface 11a of the LED die 11 that is bonded to a first electrical track 12e of the circuit board 12, and a second electrode 11d also provided on the first (lower) surface 11a of the LED die 11 that is bonded to a second electrical track 12f of the circuit board 12. In the example illustrated in FIG. 2a, both the first electrode 11c and the second electrode 11d of the lateral LED die 11 are of equal width; however, it is also possible that the first electrode 11c and the second electrode 11d of a lateral LED die 11 can be of unequal widths, as illustrated in the example embodiment of FIG. 2c.

As well as generating light, the current flow within an LED die also evolves heat which gives rise to an elevated p-n junction temperature, which in turn reduces the efficiency of light generation. Consequently, maximum light generation requires both high current and low temperature which can only be achieved by minimising the thermal resistance along the thermal path from the p-n junction to the ultimate heat rejection, which typically occurs to ambient air. In this regard, the thermal resistance of a material is a function of its thermal conductivity and material dimensions. Consequently, conventional LED packages are manufactured so as to be as small and thin as possible in order to minimise the thickness of any material that otherwise separates the light emitting element (i.e. p-n junction) of an LED die from any attached heat sink.

In view of the above, there exists a demand for an improved LED package arrangement which reduces the problems of thermal resistance associated with the LED packages of the prior art.

According to a first aspect there is provided a light emitting diode (LED) package. The LED package comprises a conductive layer disposed on a non-conductive substrate, a plurality of high aspect ratio cavities extending through the conductive layer thereby separating the conductive layer into a plurality of electrical tracks, and one or more LED die mounted on to an exposed surface of the conductive layer, each of the one or more LED die having a first electrode in electrical contact with one of the electrical tracks.

Each high aspect ratio cavity may extend through from the exposed surface of the conductive layer to the non-conductive substrate. For each high aspect ratio cavity, a width of the high aspect ratio cavity may be greater than a height of the high aspect ratio cavity. Each of the plurality of high aspect ratio cavities may be filled with a dielectric material.

The conductive layer may have a thickness of 400 μm or more.

Each of the one or more LED die may have a second electrode in electrical contact with another of the electrical tracks.

The LED package may comprise a single flip-chip LED die, the flip-chip LED die having a first electrode that is bonded to one of the electrical tracks and a second electrode that is bonded to another of the electrical tracks.

The LED package may comprise a plurality of flip-chip LED die, each flip-chip LED die having a first electrode that is bonded to one of the electrical tracks and a second electrode that is bonded to another of the electrical tracks.

The LED package may comprise a plurality of vertical LED die, each vertical LED die having a first electrode that is bonded to one of the electrical tracks and a second electrode that is connected to another of the electrical tracks by a wire bond.

The LED package may comprise a plurality of vertical LED die, each vertical LED die having a first electrode that is bonded to one of the electrical tracks.

According to a second aspect there is provided a method of manufacturing an LED package. The method comprises using a material removal process to form a plurality of high aspect ratio cavities in a conductive layer that is disposed on a non-conductive substrate, each of the high aspect ratio cavities extending through the conductive layer and thereby separating the conductive r layer into a plurality of electrical tracks. The method further comprises mounting one or more LED die on to an exposed surface of the conductive layer including, for each of the one or more LED die, forming an electrical connection between a first electrode of the LED die and one of the electrical tracks.

The material removal process may be any one of laser-ablation, water-jet machining and micro-milling.

The method may further comprise, after formation of the high aspect ratio cavities within the conductive layer, filling the cavities with a dielectric material. The step of filling the cavities with a dielectric material may comprise using any one of inkjet printing, micro-moulding, and chemical vapour deposition.

The method may further comprise, for each of the one or more LED die, forming an electrical connection between a second electrode of the LED die and another of the electrical tracks.

The method may comprise mounting a single flip-chip LED die on to the exposed surface of the conductive layer by bonding a first electrode of the LED die to one of the electrical tracks and bonding a second electrode of the LED die and another of the electrical tracks.

The method may comprise mounting a plurality of flip-chip LED die on to the exposed surface of the conductive layer by, for each of the plurality of flip-chip LED die, bonding a first electrode of the LED die to one of the electrical tracks and bonding a second electrode of the LED die and another of the electrical tracks.

The method may comprise mounting a plurality of vertical LED die on to the exposed surface of the conductive layer by, for each of the plurality of vertical LED die, bonding a first electrode of the LED die to one of the electrical tracks and forming a wire bond between a second electrode of the LED die and another of the electrical tracks.

The method may comprise mounting a plurality of vertical LED die on to the exposed surface of the conductive layer by, for each of the plurality of vertical LED die, bonding a first electrode of the LED die to one of the electrical tracks.

According to a third aspect there is provided a method of manufacturing an electronics assembly. The method comprises using a material removal process to form a plurality of high aspect ratio cavities in a conductive layer that is disposed on a non-conductive substrate, each of the high aspect ratio cavities extending through the conductive layer and thereby separating the conductive layer into a plurality of electrical tracks. The method further comprises mounting one or more electronic components on to an exposed surface of the conductive layer including, for each of the one or more electronic components, forming an electrical connection between at least one electrode of the electronic components and one of the electrical tracks.

The above and other features associated with the present invention will now be more particularly described by way of example only with reference to the accompanying drawings, in which:

FIG. 1 illustrates schematically a cross-sectional view of an example of a conventional LED module comprising a number of the conventional LED packages;

FIG. 2a illustrates schematically a cross-sectional view of an example of a conventional LED package that includes an example of a vertical LED die;

FIG. 2b illustrates schematically a cross-sectional view of an example of a conventional LED package that includes an example of a flip-chip lateral LED die;

FIG. 2c illustrates schematically a cross-sectional view of an example of a conventional LED package that includes a further example of a flip-chip lateral LED die;

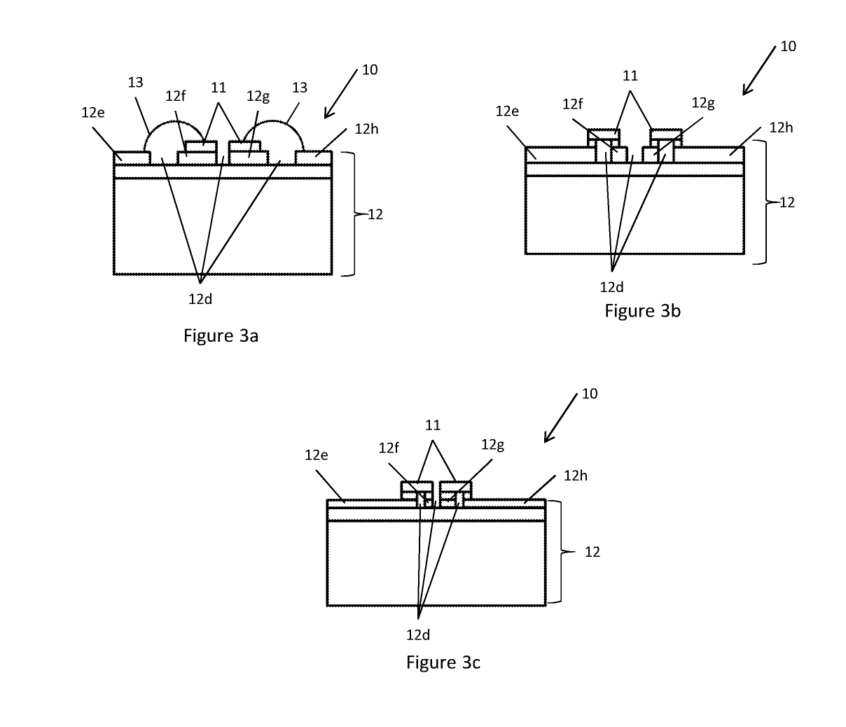

FIG. 3a illustrates schematically a cross-sectional view of an example of a conventional multi-die LED package that includes two vertical LED die;

FIG. 3b illustrates schematically a cross-sectional view of an example of a conventional multi-die LED package that includes two flip-chip lateral LED die;

FIG. 3c illustrates schematically a cross-sectional view of an example of a conventional multi-die LED package that includes two flip-chip lateral LED die;

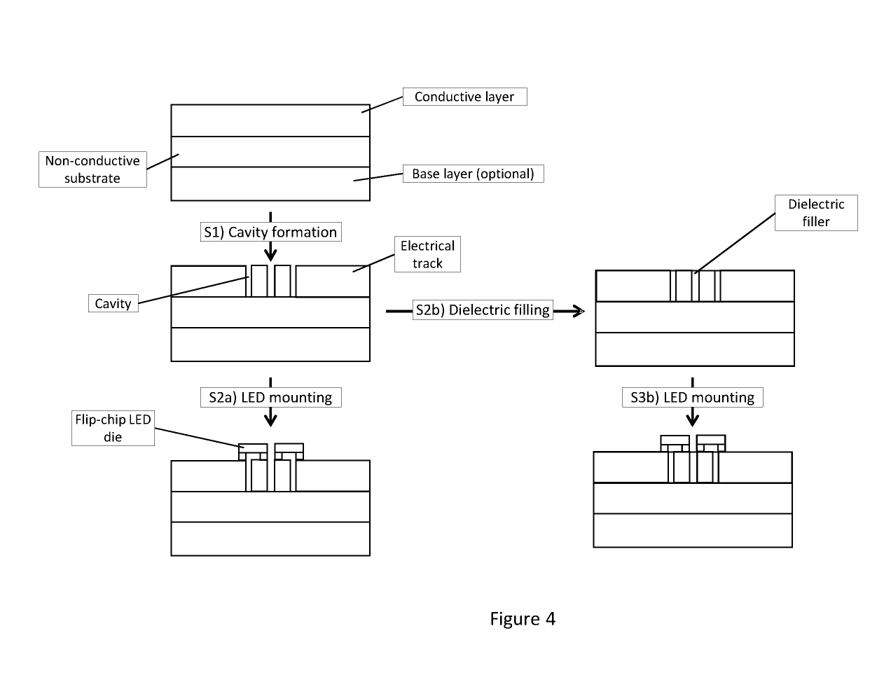

FIG. 4 illustrates schematically a process for manufacturing an improved LED package as described herein;

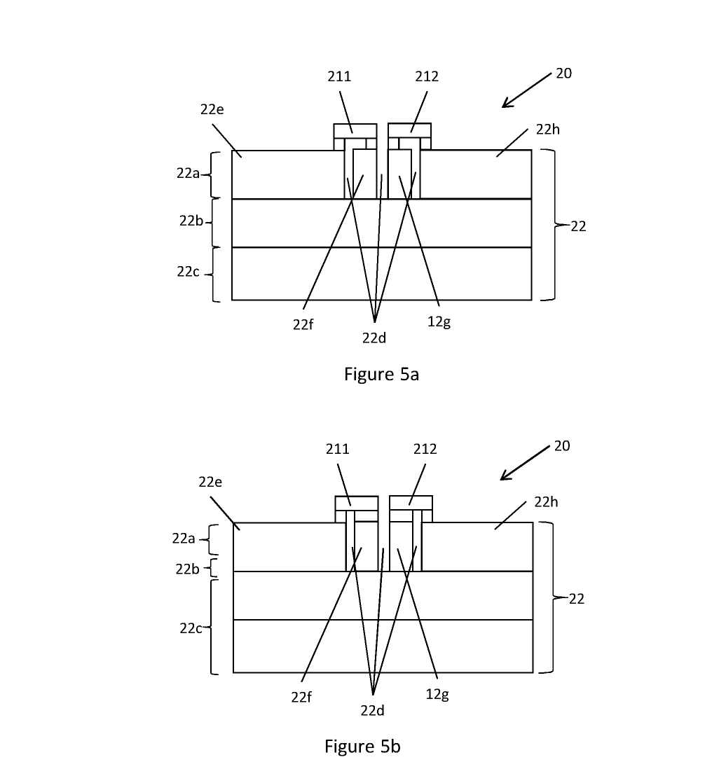

FIG. 5a illustrates schematically an example embodiment of an improved LED package as described herein; and

FIG. 5b illustrates schematically a further example embodiment of an improved LED package as described herein.

It has been recognised by the present inventors that the performance of LED packages would be greatly improved by providing a thicker top copper layer to promote heat dissipation by further reducing spreading resistance, and the present inventors have previously developed designs for LED packages in which a thick layer of copper (where thick refers to >300 μm) is disposed directly beneath the LED die as both an electrical connection and a heat spreader. These designs significantly reduce the thermal resistance but present challenges when packaging a number of LED die in close proximity as the die need to be electrically isolated. In particular, as described in more detail below, limits in the conventional etching processes used for forming electrical tracks inhibits flexibility in the placement of LED die in multi-die LED packages and thereby greatly limits the light density and optical performance of such LED packages.

Conventionally a circuit board (typically a high power circuit board such as MPCB) consists of three layers; a top copper layer, a non-conductive substrate layer, and a bottom metal layer. The top copper layer is a thin (typically 100-200 μm) copper foil, the bottom metal layer is typically comprised of either copper or aluminium, and the middle non-conductive substrate layer is typically comprised of a dielectric material such as aluminium oxide (Al2O3) or aluminium nitrite (AlN). While the metallic layers in the circuit boards have high thermal conductivity, the dielectric layer has relatively low thermal conductivity such that this represents a high thermal resistance within the thermal path. In particular, for a circuit board used within a conventional LED package, the present inventors have recognised that this high thermal resistance is compounded by the dielectric layer of the circuit board being disposed relatively close to the LED die within the thermal path, as the connecting top copper foil is too thin to allow the heat to spread and therefore dissipate before entering the thermally resistive dielectric layer.

Within a circuit board, the impact of the dielectric layer on the thermal resistance may be reduced by increasing the thickness of the top copper layer. However, the thickness of the top copper is inhibited by the conventional methods of electronics assembly that are used to form the electrical tracks in the top copper layer. In this regard, the standard copper(II) chloride (CuCl₂) etching process can only corrode material to form a cavity between the tracks where the cavity has a width no less than the thickness of the top copper before it starts to ‘undercut’ the copper track. Also, using the conventional etching process it is not possible to form copper tracks which have a height greater than their width, as they too are undercut by the etching process. This is particularly relevant for high density multi-die LED packages and modules where the LED die need to be as close together as possible, and is a critical factor for flip-chip LED die which have a very small separation between the p-electrode and n-electrode (typically 75-200 μm).

The limitations of the CuCl₂ etching process can be generalised as follows: (a) the track width must be greater than or equal to the top copper thickness, and (b) the track separation (i.e. the cavity width) must be greater than or equal to the track depth (i.e. the top copper thickness); Consequently, these limitations of the etching process require that the top copper thickness is less than or equal to the distance between the first and second electrodes of a flip-chip LED die (as the distance between the electrodes defines the maximum track separation, and the top copper thickness must be less than the track separation). FIGS. 2b and 2c therefore illustrate the maximum thickness of the top copper layer (i.e. equal to the separation between the electrodes).

This limitation in top copper thickness inherent in the etching process has a significant and detrimental impact on thermal performance. This is due to the dominant role of heat-spreading resistance as the heat dissipates from the cross-section of the LED die to that of the metal substrate (i.e. bottom metal layer). High power operation combined with high thermal resistance can cause the LED die to operate at a high temperature, thereby increasing power consumption, reducing luminous performance and ultimately the life of the semi-conductor materials leading to premature failure. Considering this, and comparing the examples shown in FIGS. 2b and 2c, the greater separation between the electrodes in the example shown in FIG. 2b allows for thicker top copper which will reduce thermal resistance of the thermal path, however, the reduced width of the electrodes that connect the LED die to the circuit board will increase thermal resistance; conversely, the larger width of the electrode in FIG. 2c will reduce thermal resistance, whilst the smaller separation between the electrodes will reduce the top copper thickness thereby increasing the thermal resistance. Consequently, it is clear that for either of the two examples shown in FIGS. 2b and 2c the thermal design of an LED package comprising a flip-chip LED die is conflicted and therefore any process for the mounting of LED die which limits the top copper thickness will also ultimately limit their thermal performance.

The limitations inherent in the etching process also have a significant impact on multi-die LED packages where flexibility in LED die placement is essential in order to be able to realise a high density luminous performance and for compatibility with modern optical lenses. In this regard, FIGS. 3a, 3b, and 3c illustrate schematically three examples of a conventional multi-die LED package 10 in which a plurality of LED die 11 (only two LED die are shown for clarity) are mounted onto a circuit board 12.

FIG. 3a illustrates schematically an example of a conventional multi-die LED package 10 that includes two vertical LED die 11. Each of the LED die 11 illustrated in FIG. 3a therefore has a wire bond 13 to an electrical track 12e, 12h provided by the top copper layer 12a of the circuit board 12 (i.e. as defined by cavities 12d formed in the top copper layer 12a). Furthermore, each of the LED die 11 are bonded to a further electrical track 12f, 12g provided by the top copper layer 12a, with the further electrical tracks 12f, 12g being separated by a cavity 12d, such that the LED die 11 are separated by a cavity 12d. FIGS. 3b and 3c then illustrate schematically examples of a conventional multi-die LED package 10 that includes two flip-chip LED die 11 in which the electrodes of the LED die 11 are each bonded to separate electrical tracks 12e, 12f, 12g, 12h provided within the top copper layer 12a of the circuit board 12 (i.e. defined by cavities 12d formed in the top copper layer 12a). Therefore, each of the LED die 11 are separated by a cavity 12d. Once again, the separation between the electrical tracks 12e, 12f, 12g, 12h, and therefore between the LED die 11 is limited by the thickness of the top copper 12a.

According to the above stated limitations in the etching process regarding track width, depth and separation, the distance between adjacent LED in a multi-die LED package (referred to here as ‘die separation’) is also limited to the minimum track separation and therefore must be greater than or equal to the top copper thickness. In other words, the die separation cannot be less than the minimum track separation which is equal to the track depth/top copper thickness. FIGS. 3a, 3b and 3c therefore illustrate the minimum die separation for a multi-die LED package (i.e. equal to the top copper thickness).

Considering this and comparing the examples illustrated in FIGS. 3b and 3c, the greater top copper thickness in the example shown in FIG. 3b; conversely the thinner top copper in shown in the example of FIG. 3c allows for closer proximity of die placement, but increases thermal resistance. Consequently, it is clear that for any of the examples shown in FIGS. 3a, 3b, and 3c the die placement is compromised, and therefore any process for the mounting of LED die which limits the top copper thickness will also ultimately limit their optical performance.

These limitations in the thermal and optical performance for the assembly of LED die into packages and modules caused by the requirements of the conventional etching processes creates a need for an alternative method of forming the electrical tracks in the circuit board of an LED package that does not compromise the die placement or thermal path. This is particularly true for advantageous LED package arrangements in which in which a relatively thick layer of copper (where thick refers to >300 μm) is disposed directly beneath the LED die as both an electrical connection and a heat spreader.

Consequently, the present inventors have developed a process for manufacturing improved LED packages in which the conventional etching processes used for forming electrical tracks in a conductive layer of a circuit board are replaced by a material removal process capable of generating high-aspect ratio micro-channels/cavities. In other words, the height of each cavity is greater than the width, the height being the distance the cavity extends through from the exposed surface of the conductive layer to the non-conductive substrate and the width being perpendicular to the height. Doing so removes the limitations on the thickness of the conductive layer, such that the non-conductive substrate dielectric layer can be distanced from the LED die within the thermal path (i.e. when compared with how close the dielectric layer is to the LED die in a conventional LED package), and allows the thermal and electrical paths to be decoupled such that both of these aspects can be optimised independently. Preferably, the height to width ratio of such a high-aspect ratio cavity is 3:1 or greater, so as to allow for a thick conductive layer relative to conventional LED packages, and more preferably between 3:1 and 5:1, as such a ratio optimises the thickness of the conductive layer relative to the separation between the electrical tracks, and therefore optimises the thermal and optical performance for the LED package.

FIG. 4 illustrates schematically a process for manufacturing an improved LED package. The steps performed are as follows:
S1. A material removal process is used to form a plurality of high aspect ratio cavities in a thick (i.e. >300 μm) conductive layer (e.g. copper or aluminium etc) that has been laminated onto a non-conductive (i.e. dielectric) substrate. The high aspect ratio cavities formed in the conductive layer define a plurality of electrical tracks. In other words, the cavities separate the conductive layer into a plurality of electrical tracks. By way of example, material removal process capable of generating high-aspect ratio cavities include but are not limited to laser-ablation, water-jet machining, spark erosion, and micro-milling. The process then proceeds to either step S2a or step S2b.
S2a. One or more LED die are then mounted onto the exposed surface of the conductive layer. In this regard, each LED die is provided with a first electrode and a second electrode, and the mounting of an LED die to the conductive layer involves forming an electrical contact between at least the first electrode and one of the electrical tracks formed in the conductive layer. Depending upon the particular requirements, the mounting of an LED die to the conductive layer could also involve forming a further electrical contact between the second electrode and another of the electrical tracks provided by the conductive layer. For example, whilst the LED packages illustrated in FIG. 4 comprise a plurality of flip-chip LED die, for which both the first and second electrode are directly bonded to separate electrical tracks, the process is equally applicable to vertical LED die. For vertical LED die, the first (i.e. lower electrode is directly bonded to one of the electrical tracks. The second (i.e. upper) electrode can then either be electrically connected to another of the electrical tracks by a wire bond, or alternatively could be electrically connected to a circuit board that is external to the LED package by a wire bond (i.e. when the LED package is included within an module).
S2b. Optionally, after the formation of the cavities within the conductive layer, the cavities can be filled with a dielectric material so as to improve the electrical isolation of the electrical tracks. By way of example, the dielectric material could be a material such as aluminium oxide (Al₂O₃), aluminium nitrite (AlN) or a polymeric material. The filling of the cavities with dielectric can then be achieved using, for example, inkjet printing, injection moulding, micro-moulding etc. Alternatively, a process such as chemical vapour deposition can be used to fill the micro-channels/cavities with dielectric. The process then proceeds to either step S3b.

S3b. After the filling of the cavities with a dielectric material, one or more LED die are then mounted onto the exposed surface of the conductive layer, as per step S2a.

FIG. 5a therefore illustrates an example of an improved LED package 20. The LED package 20 comprises one or more LED die (two are shown for the purposes of clarity) 211, 212 mounted onto a circuit board 22 wherein the circuit board 22 consists of at least two layers; a conductive layer 22a, and a non-conductive substrate/dielectric layer 22b. Optionally, the circuit board 22 can also comprise a base (bottom) layer 22c. For example, the base layer could be a layer of glass-reinforced plastic to provide additional rigidity to the circuit board. As described above, the conductive layer 22a of the circuit board 22 is thick (i.e. >300 μm) and is processed to generate a number of high-aspect ratio cavities 22d, wherein the cavities 22d separate portions of the conductive layer 22a so as to define a number of electrical tracks 22e, 22f, 22g, 22h. For example, a typical high-aspect ratio cavity could be 100p.m wide and 500p.m deep/high would be typical.

The LED die 211, 212 illustrated in FIG. 4a are flip-chip LED die that therefore each have both a first electrode and a second electrode provided on the first (lower) surface of the LED die. The first electrode of the first LED die 211 is bonded to a first electrical track 22e of the circuit board 22, and the second electrode of the first LED die 211 is bonded to a second electrical track 22f of the circuit board 12. Similarly, the first electrode of the second LED die 212 is bonded to a third electrical track 22g of the circuit board 22, and the second electrode of the second LED die 212 is bonded to a fourth electrical track 22h of the circuit board 22. Consequently, the first LED die 211 and the second LED die 212 are separated by one of the cavities 22d formed within the conductive layer 22a.

In the example illustrated in FIG. 5a, both the first electrode and the second electrode of each of the LED die 211, 212 are of equal width; however, it is also possible that the first electrode and the second electrode of each LED die 11 can be of unequal widths, as illustrated in the example embodiment of FIG. 5b.

Optionally, prior to the mounting of the LED die on to the circuit board 22, the circuit board 22 can be further processed in order to fill the cavities formed in the conductive layer 22a with a dielectric material. The improved LED package 20 would then comprise a plurality of (vertical) seams/strips of dielectric material separating the electrical tracks 22e, 22f, 22g, 22h provided by the conductive layer 22. The filling of the cavities with a dielectric material is advantageous for cases where the accumulation of forward voltage across an array of multiple LED die in series could cause an electrical arc risk between the electrodes of adjacent die.

Whilst the improved LED packages described above with reference to FIGS. 5a and 5b comprise a plurality of flip-chip LED die, the ability to form high-aspect ratio cavities that define electrical tracks in a thick conductive layer is equally applicable to LED packages that comprise a single flip-chip LED die, as the thickness of the conductive layer is then not limited by the maximum cavity width that is defined by the separation of the first and second electrodes of a flip-chip LED die.

In addition, the ability to form high-aspect ratio cavities to define electrical tracks in a thick conductive r layer is also equally applicable to LED packages that comprise a plurality of vertical LED die, in which each of the vertical LED die has a first electrode provided on a first (lower) surface of the LED die and a second electrode provided on a second opposite (upper) surface of the LED die, with at least the first electrode being bonded to one of the electrical tracks defined by the high-aspect ratio cavities.

In contrast with conventional LED packages, the minimum width of the cavities of the improved LED package described herein are not limited by the thickness of the conductive layer, such that the thickness of the conductive layer does not limit the distance between adjacent LED die. In addition, the maximum thickness of the conductive layer is no longer limited by the separation of the electrodes of a flip-chip LED die. Consequently, a thicker conductive layer can be used. The io improved LED package described above therefore has a lower thermal resistance than a conventional LED package whilst also allowing flexibility in the placement of multiple LED die, thereby providing both improved thermal performance and higher luminous density.

It will be appreciated that individual items described above may be used on their own or in combination with other items shown in the drawings or described in the description and that items mentioned in the same passage as each other or the same drawing as each other need not be used in combination with each other. In addition, the expression “means” may be replaced by actuator, system, unit or device as may be desirable.

Furthermore, although the invention has been described in terms of preferred embodiments as set forth above, it should be understood that these embodiments are illustrative only. Those skilled in the art will be able to make modifications and alternatives in view of the disclosure which are contemplated as falling within the scope of the appended claims.

By way of example, whilst the embodiments illustrated in FIGS. 4, 5a, and 5b show multi-die LED packages in which adjacent LED die are separated by one of the cavities formed in the conductive layer, such that each of the LED die are electrically isolated from one another, it is possible that multiple LED die within an LED package could share one or more electrical tracks. In particular, multiple LED die within an LED package could be connected in parallel sets that have common p and n electrodes, with these sets of multiple parallel LED die being connected in series. In other words, multiple LED die within an LED package could have electrical connections in common, and may be arranged in parallel and serial sets.

In addition, whilst the methods described herein have been described in terms of the manufacture of LED packages it is equally applicable to the manufacture of other types of electronic assemblies in which one or more electronic components need to be mounted onto a circuit board for incorporation into a device, wherein a circuit board is any substrate that provides mechanical support for and electrical connections to the electronic components mounted thereon.

1. A light emitting diode (LED) package comprising:
a conductive layer;
a plurality of high aspect ratio cavities extending through the conductive layer thereby separating the conductive layer into a plurality of electrical tracks; and
one or more LED die mounted [[on to]] onto an exposed surface of the conductive layer, each of the one or more LED die having a first electrode in electrical contact with one of the electrical tracks characterized in that:
the conductive layer has a thickness of at least 300 μm and is disposed on a non-conductive substrate through which the high aspect ratio cavities do not extend.

2. The LED package of claim 1, wherein, for each high aspect ratio cavity, a height of the cavity is greater than the width of the cavity.

3. The LED package of claim 1, wherein, for each high aspect ratio cavity, the height to width ratio of the cavity is 3:1 or greater and is preferably between 3:1 and 5:1.

4. The LED package of claim 1, wherein each of the plurality of high aspect ratio cavities is filled with a dielectric material.

5. The LED package of claim 1, wherein the conductive layer has a thickness of between 300 μm and 700 μm.

6. The LED package of claim 1, wherein each of the one or more LED die has a second electrode in electrical contact with another of the electrical tracks.

7. The LED package of claim 6, wherein the LED package comprises a single flip-chip LED die, the flip-chip LED die having a first electrode that is bonded to one of the electrical tracks and a second electrode that is bonded to another of the electrical tracks.

8. The LED package claim 6, wherein the LED package comprises a plurality of flip-chip LED die, each of the plurality of flip-chip LED die having a first electrode that is bonded to one of the electrical tracks and a second electrode that is bonded to another of the electrical tracks.

9. The LED package of claim 6, wherein the LED package comprises a plurality of vertical LED die, each vertical LED die having a first electrode that is bonded to one of the electrical tracks and a second electrode that is connected to another of the electrical tracks by a wire bond.

10. The LED package of claim 1, wherein the LED package comprises a plurality of vertical LED die, each vertical LED die having a first electrode that is bonded to one of the electrical tracks.

11. A method of manufacturing a light emitting diode (LED) package comprising:
using a material removal process to form a plurality of high aspect ratio cavities in a conductive layer, each of the high aspect ratio cavities extending through the conductive layer and thereby separating the conductive layer into a plurality of electrical tracks; and
mounting one or more LED die onto an exposed surface of the conductive layer including, for each of the one or more LED die, forming an electrical connection between a first electrode of the LED die and one of the electrical tracks;
characterized by:
disposing the conductive layer on a non-conductive substrate through which the high aspect ratio cavities do not extend, such that the conductive layer has a thickness of at least 300 μm.

12. The method of claim 11, wherein the height to width ratio of each high aspect ratio cavity is 3:1 or greater and is preferably between 3:1 and 5:1.

13. (canceled)

14. The method as of claim 11, further comprising:
after formation of the high aspect ratio cavities within the conductive layer, filling the high aspect ratio cavities with a dielectric material.

15. The method as of claim 14, wherein the step of filling the high aspect ratio cavities with the dielectric material comprises using any one of inkjet printing, micro-molding, and chemical vapor deposition.

16. The method of claim 11, further comprising, for each of the one or more LED die, forming an electrical connection between a second electrode of the LED die and another of the electrical tracks.

17. The method of claim 16, wherein a single flip-chip LED die is mounted onto the exposed surface of the conductive layer by bonding a first electrode of the LED die to one of the electrical tracks and bonding a second electrode of the LED die to another of the electrical tracks.

18. The method of claim 16, wherein a plurality of flip-chip LED die are mounted onto the exposed surface of the conductive layer by, for each of the plurality of flip-chip LED die, bonding a first electrode of the LED die to one of the electrical tracks and bonding a second electrode of the LED die to another of the electrical tracks.

19. The method of claim 16, wherein a plurality of vertical LED die are mounted onto the exposed surface of the conductive layer by, for each of the plurality of vertical LED die, bonding a first electrode of the LED die to one of the electrical tracks and forming a wire bond between a second electrode of the LED die and another of the electrical tracks.

20. The method of claim 11, wherein a plurality of vertical LED die are mounted onto the exposed surface of the conductive layer by, for each of the plurality of vertical LED die, bonding a first electrode of the LED die to one of the electrical tracks.

21. A method of manufacturing an electronics assembly comprising:
using a material removal process to form a plurality of high aspect ratio cavities in a conductive layer, each of the high aspect ratio cavities extending through the conductive layer and thereby separating the conductive layer into a plurality of electrical tracks; and
mounting one or more electronic components onto an exposed surface of the conductive layer including, for each of the one or more electronic components, forming an electrical connection between at least one electrode of the electronic components and one of the electrical tracks;
characterized by:
disposing the conductive layer on a non-conductive substrate through which the high aspect ratio cavities do not extend, such that the conductive layer has a thickness of at least 300 μm.
